(19) United States
(12) Patent Application Publication
(10) Pub. No.: US 2022/0013989 A1
(43) Pub. Date: Jan. 13, 2022

(54) SEMICONDUCTOR LASER AND ELECTRONIC APPARATUS

(71) Applicant: SONY SEMICONDUCTOR SOLUTIONS CORPORATION, KANAGAWA (JP)

(72) Inventors: KOTA TOKUDA, KANAGAWA (JP); SHINYA SATOU, KANAGAWA (JP)

(21) Appl. No.: 17/291,859

(22) PCT Filed: Oct. 31, 2019
(86) PCT No.: PCT/JP2019/042758

§ 371 Date: May 6, 2021

(30) Foreign Application Priority Data
Nov. 15, 2018 (JP) 2018-214956

(51) Int. Cl. H01S 5/223; H01S 5/343; H01S 5/16

(52) U.S. Cl. CPC H01S 5/2231; H01S 5/162; H01S 5/343

(57) ABSTRACT

A semiconductor laser according to an embodiment of the present disclosure includes a semiconductor stack section. The semiconductor stack section includes a first semiconductor layer of a first conductivity type, a second semiconductor layer of a second conductivity type, in which the second semiconductor layer is stacked on the first semiconductor layer and includes a ridge having a band shape, and an active layer. The semiconductor stack section further has an impurity region that is at least a portion of a region not facing the ridge and that is located at a position deeper than at least the active layer, in which the impurity region has an impurity concentration of the second conductivity type higher than an impurity concentration of the second conductivity type in a region, of the second semiconductor layer, facing the ridge.

### TECHNICAL FIELD

The present disclosure relates to a semiconductor laser and an electronic apparatus including the same.

### BACKGROUND ART

An edge emission type semiconductor laser is disclosed in, for example, the following Patent Literatures 1 to 3.

### CITATION LIST

### Patent Literature

Patent Literature 1: Japanese Unexamined Patent Application Publication No. H04-303983
Patent Literature 2: Japanese Unexamined Patent Application Publication No. 2012-182375
Patent Literature 3: Japanese Unexamined Patent Application Publication No. 2012-182374

### SUMMARY OF THE INVENTION

In a case where a ridge is provided in a semiconductor laser of an edge emission type, a current leakage to both sides of the ridge occurs, lowering a utilization efficiency of a current and making it not possible to obtain a good threshold current in some cases. Accordingly, it is desirable to provide a semiconductor laser that makes it possible to suppress a current leakage to both sides of a ridge and an electronic apparatus including the same.

A semiconductor laser according to one embodiment of the present disclosure includes a semiconductor stack section. The semiconductor stack section includes a first semiconductor layer of a first conductivity type, a second semiconductor layer of a second conductivity type, in which the second semiconductor layer is stacked on the first semiconductor layer and includes a ridge having a band shape, and an active layer. The semiconductor stack section further has an impurity region that is at least a portion of a region not facing the ridge and that is located at a position deeper than at least the active layer, in which the impurity region has an impurity concentration of the second conductivity type higher than an impurity concentration of the second conductivity type in a region, of the second semiconductor layer, facing the ridge.

An electronic apparatus according to one embodiment of the present disclosure includes a semiconductor laser as a light source. The semiconductor laser provided in the electronic apparatus has a configuration similar to that of the semiconductor laser described above.

In the semiconductor laser and the electronic apparatus according to one embodiment of the present disclosure, the impurity region that is at least a portion of the region not facing the ridge and that is located at the position deeper than at least the active layer is provided. The impurity region has the impurity concentration of the second conductivity type higher than the impurity concentration of the second conductivity type in the region, of the second semiconductor layer, facing the ridge. This prevents electrons or holes from being transported to the active layer on both sides of the ridge.

### BRIEF DESCRIPTION OF THE DRAWINGS

FIG. 1 is a diagram illustrating an example of a configuration of an upper surface of a semiconductor laser according to a first embodiment of the present disclosure.

FIG. 2 is a diagram illustrating an example of a cross-sectional configuration of the semiconductor laser illustrated in FIG. 1 taken along the line A-A.

FIG. 3 is a diagram illustrating an example of a cross-sectional configuration of the semiconductor laser illustrated in FIG. 1 taken along the line B-B.

FIG. 4 is a diagram illustrating an example of a planar configuration of a second region and a fourth region of the semiconductor laser illustrated in FIG. 2.

FIG. 5 is a diagram illustrating an example of a relationship between a p-type impurity concentration in the second region and an amount of reduction of a threshold current.

FIG. 6 is a diagram illustrating an example of current paths in a semiconductor laser according to one embodiment.

FIG. 7 is a diagram illustrating an example of current paths in a semiconductor laser according to a comparative example.

FIG. 8 is a diagram illustrating an example of a relationship of a distance between a bottom surface of the second region and the active layer versus the amount of reduction of the threshold current.

FIG. 9 is a diagram illustrating an example of threshold currents of the semiconductor lasers according to the comparative example and one embodiment.

FIG. 10A is a diagram illustrating an example of a manufacturing method of the semiconductor laser illustrated in FIG. 1.

FIG. 10B is a diagram illustrating an example of a manufacturing process following FIG. 10A.

FIG. 10C is a diagram illustrating an example of a manufacturing process following FIG. 10B.

FIG. 10D is a diagram illustrating an example of a manufacturing process following FIG. 10C.

FIG. 10E is a diagram illustrating an example of a manufacturing process following FIG. 10D.

FIG. 10F is a diagram illustrating an example of a manufacturing process following FIG. 10E.

FIG. 10G is a diagram illustrating an example of a manufacturing process following FIG. 10F.

FIG. 10H is a diagram illustrating an example of a manufacturing process following FIG. 10G.

FIG. 10I is a diagram illustrating an example of a manufacturing process following FIG. 10H.

FIG. 10J is a diagram illustrating an example of a manufacturing process following FIG. 10I.

FIG. 11 is a diagram illustrating one modification example of a cross-sectional configuration of the semiconductor laser illustrated in FIG. 2.

FIG. 12 is a diagram illustrating one modification example of a cross-sectional configuration of the semiconductor laser illustrated in FIG. 3.

FIG. 13 is a diagram illustrating one modification example of a cross-sectional configuration of the semiconductor laser illustrated in FIG. 2.

FIG. 14 is a diagram illustrating one modification example of a cross-sectional configuration of the semiconductor laser illustrated in FIG. 11.

FIG. 15 is a diagram illustrating one modification example of a cross-sectional configuration of the semiconductor laser illustrated in FIG. 2.

FIG. 16 is a diagram illustrating one modification example of a cross-sectional configuration of the semiconductor laser illustrated in FIG. 11.

FIG. 17 is a diagram illustrating one modification example of a cross-sectional configuration of the semiconductor laser illustrated in FIG. 2.

FIG. 18 is a diagram illustrating one modification example of a cross-sectional configuration of the semiconductor laser illustrated in FIG. 11.

FIG. 19 is a diagram illustrating one modification example of a cross-sectional configuration of the semiconductor laser illustrated in FIG. 2.

FIG. 20 is a diagram illustrating one modification example of a cross-sectional configuration of the semiconductor laser illustrated in FIG. 11.

FIG. 21 is a diagram illustrating an example of a schematic configuration of a distance measuring apparatus according to a second embodiment of the present disclosure.

FIG. 22 is a diagram illustrating an example of a schematic configuration of a projector according to a third embodiment of the present disclosure.

### MODES FOR CARRYING OUT THE INVENTION

Hereinafter, an embodiment of the present disclosure is described in detail with reference to the drawings. The following description is a specific example of the present disclosure, but the present disclosure is not limited to the following embodiment. Moreover, the present disclosure does not limit the disposition, dimensions, dimension ratios, and the like of respective components illustrated in the drawings thereto. It is to be noted that the description is given in the following order.
1. First Embodiment (semiconductor laser)
2. Modification Examples (semiconductor laser)
3. Second Embodiment (distance measuring apparatus)
4. Third Embodiment (projector)

### 1. FIRST EMBODIMENT

[Configuration]

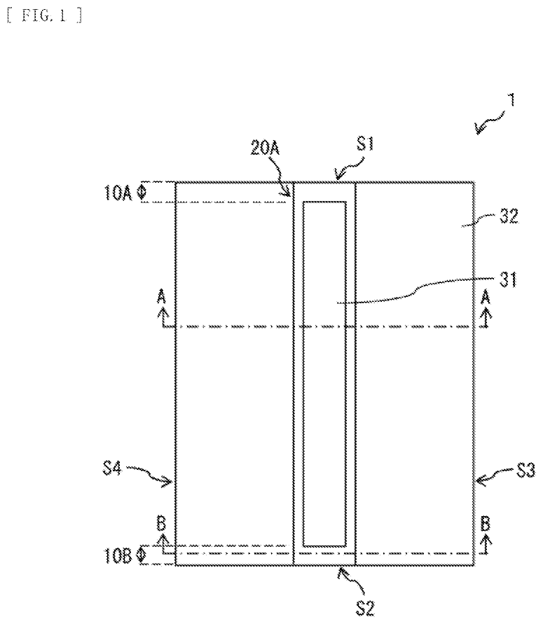

A semiconductor laser 1 according to a first embodiment of the present disclosure will be described. FIG. 1 illustrates an example of a configuration of an upper surface of the semiconductor laser 1 according to the present embodiment. The semiconductor laser 1 has a structure in which a later-described semiconductor stack section 20 is sandwiched between a pair of resonator end faces S1 and S2 in a resonator direction. The resonator end face S1 is a front end face in which laser light is to be outputted to the outside, and the resonator end face S2 is a rear end face disposed to face the resonator end face S1. Accordingly, the semiconductor laser 1 is a kind of so-called edge emission type semiconductor laser.

The semiconductor laser 1 (the semiconductor stack section 20) includes the resonator end faces S1 and S2 facing each other in the resonator direction, and a ridge 20A having a convex shape and sandwiched between the resonator end face S1 and the resonator end face S2. The ridge 20A has a band shape extending in the resonator direction. The ridge 20A is formed, for example, by being etched and removed from a surface of a later-described contact layer 26 to the middle of a later-described upper cladding layer 25. That is, a portion of the upper cladding layer 25 is formed on both sides of the ridge 20A.

A width of the ridge 20A is, for example, 0.5 μm or more and 5.0 μm or less. One end face of the ridge 20A is exposed from the resonator end face S1 and the other end face of the ridge 20A is exposed from the resonator end face S2. The resonator end faces S1 and S2 are each a plane formed by cleavage. The resonator end faces S1 and S2 each function as a resonator mirror, and the ridge 20A functions as an optical waveguide. The resonator end face S1 is provided with a reflection preventing film configured to cause a reflectivity at the resonator end face S1 to be about 15%, for example. The resonator end face S2 is provided with a multilayer reflection film configured to allow a reflectivity at the resonator end face S2 to be about 85%. The semiconductor laser 1 (the semiconductor stack section 20) further has end faces S3 and S4 that face each other in a direction intersecting the resonator direction (hereinafter, referred to as a “width direction”). That is, the end face S3 and S4 are formed on both sides of the ridge 20A. The end faces S3 and S4 are faces formed by cutting by means of dicing.

Window structures 10A and 10B are provided at both ends of the ridge 20A. The window structure 10A is formed in a region that includes the resonator end face S1, and the window structure 10B is formed in a region that includes the resonator end face S2. The window structure 10A and 10B suppress instability of oscillation resulting from a current flowing in the vicinity of the resonator end faces S1 and S2. The window structure 10B is not provided with the contact layer 26 or an upper electrode layer 31 to be described later. Accordingly, a current is not directly injected from the upper electrode layer 31 into the window structure 10B. The window structures 10A and 10B may be omitted as necessary. An insulation layer 32 is formed on a surface of the semiconductor laser 1 (the semiconductor stack section 20). The insulation layer 32 protects the semiconductor stack section 20 and defines a region in which a current is to be injected into the semiconductor stack section 20 (i.e., a region in which the semiconductor stack section 20 and the upper electrode layer 31 are in contact with each other).

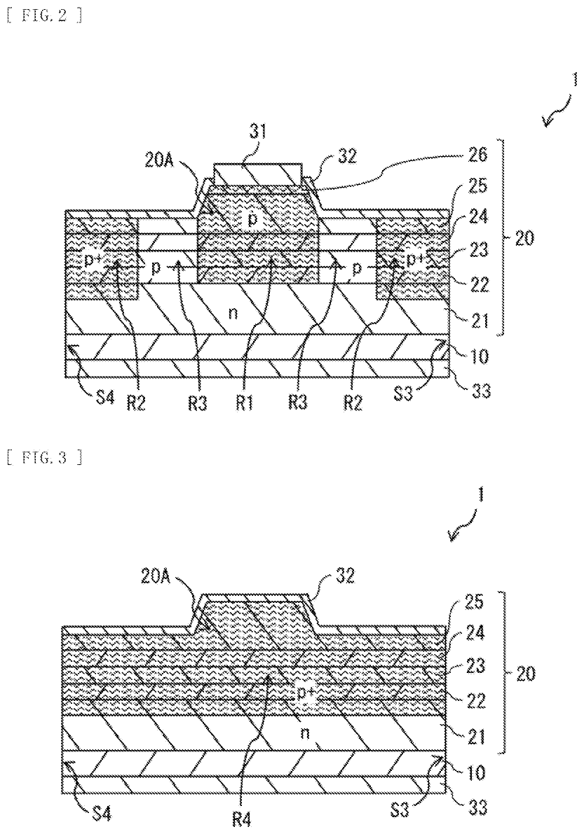

FIG. 2 illustrates an example of a cross-sectional configuration of the semiconductor laser 1 taken along the line A-A. FIG. 3 illustrates an example of a cross-sectional configuration of the semiconductor laser 1 taken along the line B-B. FIG. 2 illustrates an example of the cross-sectional configuration of a middle portion in the resonator direction (an extending direction of the ridge 20A) of the semiconductor laser 1. FIG. 3 illustrates an example of the cross-sectional configuration in the vicinity of the resonator end faces S1 and S2 (the window structures 10A and 10B) of the semiconductor laser 1.

The semiconductor laser 1 includes the semiconductor stack section 20 on a substrate 10. The semiconductor stack section 20 has, for example, a lower cladding layer 21, a lower guide layer 22, an active layer 23, an upper guide layer 24, the upper cladding layer 25, and the contact layer 26 in this order from the substrate 10. The lower cladding layer 21 and the lower guide layer 22 correspond to a specific example of a “first semiconductor layer” of the present disclosure. The upper guide layer 24, the upper cladding layer 25, and the contact layer 26 correspond to a specific example of a “second semiconductor layer” of the present disclosure. Note that the semiconductor stack section 20 may be provided with a layer other than the above-described layers (e.g., a buffer layer or the like).

The substrate 10 is, for example, an Si-doped n-type GaAs substrate. The semiconductor stack section 20 includes, for example, an AlₓGa₁₋ₓAs-based semiconductor material (0≤x<1). The semiconductor stack section 20 has a configuration in which a p-type semiconductor layer is stacked on an n-type semiconductor layer. The n-type corresponds to a specific example of a “first conductivity type” of the present disclosure. The p-type corresponds a specific example of a “second conductivity type” of the present disclosure. In the semiconductor stack section 20, the lower cladding layer 21 corresponds to the n-type semiconductor layer, and the lower guide layer 22, the active layer 23, the upper guide layer 24, the upper cladding layer 25, and the contact layer 26 correspond to the p-type semiconductor layer. That is, the active layer 23 is provided in the p-type semiconductor layer.

The lower cladding layer 21 includes, for example, an Si-doped n-type Alₓ₁Ga₁₋ₓ₁As. The lower guide layer 22 includes, for example, a C-doped p-type Alₓ₂Ga₁₋ₓ₂As. The active layer 23 has, for example, a multi-quantum well structure. For example, the multi-quantum well structure has a structure in which a barrier layer and a well layer are stacked alternately. The barrier layer includes, for example, Alₓ₃Ga₁₋ₓ₃As. The well layer includes, for example, Alₓ₄Ga₁₋ₓ₄As (x4>x3). In the active layer 23, a dopant and a doping concentration in the multi-quantum well structure structuring the active layer 23 are adjusted so that an average electric characteristic of the active layer 23 becomes the p-type. The upper guide layer 24 includes, for example, a C-doped p-type Alₓ₅Ga₁₋ₓ₅As. The upper cladding layer 25 includes, for example, a C-doped p-type Alₓ₆Ga₁₋ₓ₆As. The contact layer 26 includes, for example, a C-doped p-type GaAs.

The semiconductor laser 1 further includes an upper electrode layer 31 on the semiconductor stack section 20 and a lower electrode layer 33 on the back surface side of the semiconductor stack section 20.

The upper electrode layer 31 is formed on the ridge 20A, and is in contact with the contact layer 26 formed on an upper part of the ridge 20A. The upper electrode layer 31 is in contact with a portion of an upper surface of the ridge 20A excluding the window structures 10A and 10B. The upper electrode layer 31 has a configuration in which, for example, a Ti layer, a Pt layer, and an Au layer are stacked in this order from the side closer to the ridge 20A. The upper electrode layer 31 may be electrically coupled to the upper surface of the ridge 20A, and a layer configuration is not limited to the above configuration.

The lower electrode layer 33 is formed, for example, in contact with the back surface of the substrate 10. The lower electrode layer 33 has a configuration in which, for example, a Ti layer and an Al layer are stacked in this order from the side closer to the substrate 10. The lower electrode layer 33 may be electrically coupled to the substrate 10, and a layer configuration is not limited to the above configuration. In addition, the lower electrode layer 33 may be in contact with the entire back surface of the substrate 10, or may be in contact with only a portion of the back surface of the substrate 10.

Next, impurity regions (a first region R1, a second region R2, a third region R3, and a fourth region R4) provided in the semiconductor stack section 20 will be described.

The semiconductor stack section 20 has a first region R1 in a region facing the ridge 20A. The first region R1 is formed in the p-type semiconductor layer in the semiconductor stack section 20. The first region R1 is formed from the contact layer 26 up to a depth that reaches the lower guide layer 22 in the semiconductor stack section 20, for example. The first region R1 is formed so as to extend in the resonator direction. The first region R1 is formed in a region other than the window structures 10A and 10B in the semiconductor stack section 20, for example. The first region R1 is an impurity region containing a p-type impurity. The p-type impurity contained in the first region R1 is, for example, C. The p-type impurity concentration in the first region R1, for example, has a value in a range of 1.0×10¹⁶ cm⁻³ or more and 4.0×10¹⁸ cm⁻³ or less.

The semiconductor stack section 20 has the second region R2 on each of both sides of the ridge 20A. The second region R2 corresponds to a specific example of a “first impurity region” of the present disclosure. The second regions R2 are formed at respective positions that are on both sides of the ridge 20A and that are deeper than at least the active layer 23 in the semiconductor stack section 20. The second regions R2 are each formed not only in the p-type semiconductor layer in the semiconductor stack section 20 but also up to the inside of the n-type semiconductor layer. The second regions R2 are each provided in the semiconductor stack section 20 from a portion corresponding to the foot of the ridge 20A (an upper surface of the upper cladding layer 25) to a position deeper than the active layer 23. The second regions R2 are each formed, for example, in the semiconductor stack section 20 from the portion corresponding to the foot of the ridge 20A (the upper surface of upper the cladding layer 25) up to a depth that reaches the lower cladding layer 21.

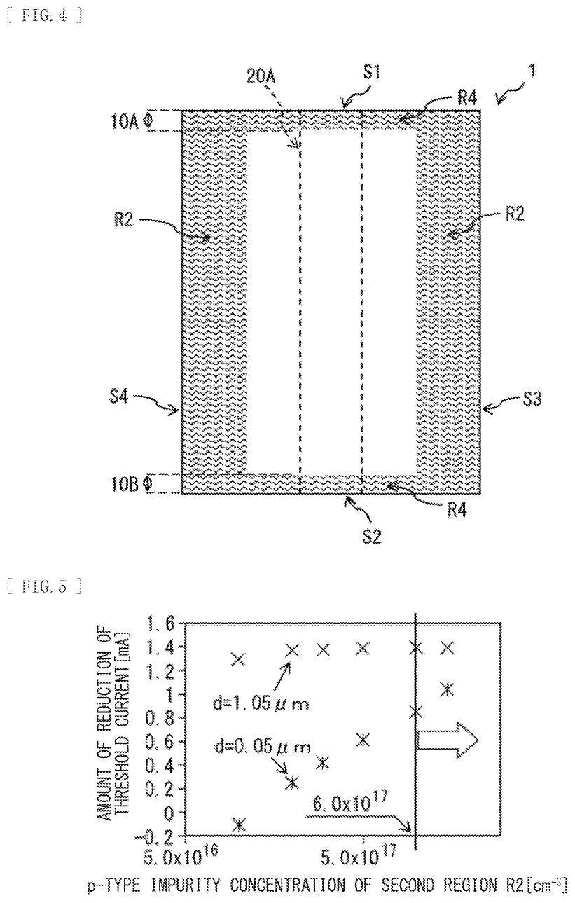

For example, as illustrated in FIG. 4, the second regions R2 are each formed to extend in the resonator direction, and are each formed in a region other than the window structures 10A and 10B in the semiconductor stack section 20, for example. One of the second regions R2 is further formed in a region that includes the end face S3, for example, as illustrated in FIG. 4. The other second region R2 is further formed in a region that includes the end face S4, for example, as illustrated in FIG. 4. The second regions R2 are each an impurity region containing a p-type impurity. The p-type impurity contained in each of the second regions R2 is, for example, Zn. The p-type impurity concentration in each of the second regions R2 is higher than the p-type impurity concentration in the first region R1, and has, for example, a value in a range of 1.0×10¹⁷ cm⁻³ or more and 2.0×10¹⁹ cm⁻³ or less. The p-type impurity concentration in each of the second regions R2 is preferably 6.0×10¹⁷/cm³ or more, for example, as illustrated in FIG. 5. Note that a horizontal axis of FIG. 5 is the p-type impurity concentration of the second region R2, and a vertical axis of FIG. 5 is an amount of reduction of a threshold current. FIG. 5 illustrates simulation results where a distance d from a bottom surface (i.e., a p-n junction described above) of the second region R2 to the active layer 23 was 0.05 μm and where the distance d was 1.05 μm. It can be appreciated from FIG. 5 that the amount of reduction of the threshold current, where the distance d is very narrow (d=0.05 μm), becomes 50% or more of the amount of reduction of the threshold current (=1.4 mA), where the amount of reduction of the threshold current becomes the greatest (the distance d (=1.05 μm)), is when the p-type impurity concentration in each of the second regions R2 is 6.0×10¹⁷/cm³ or more.

In the first region R1, the p-type impurity concentration and a composition ratio of constituent materials do not have to be uniform. In the first region R1, the p-type impurity concentration and the composition ratio of the constituent materials may be gradually changed depending on a position. Further, the first region R1 may be configured by a plurality of layers in which the p-type impurity concentrations and the composition ratios of the constituent materials are different from each other. In the second region R2, the p-type impurity concentration and a composition ratio of constituent materials do not have to be uniform. In the second region R2, the compositional ratio of the p-type impurity concentration and the composition ratio of the constituent materials may be gradually changed depending on a position. Further, the second region R2 may be configured by a plurality of layers in which the p-type impurity concentrations and the composition ratios of the constituent materials are different from each other. In any case, it is preferable that the p-type impurity concentration in the second region R2 be higher than the p-type impurity concentration in the first region R1 at the common depth.

The semiconductor stack section 20 has the third region R3 on each of both sides of the ridge 20A. The third regions R3 are each positioned between the ridge 20A and the second region R2, and are each positioned in a region other than the window structures 10A and 10B. The third regions R3 are each an impurity region containing a p-type impurity. The p-type impurity contained in each of the third regions R3 is, for example, C. The p-type impurity concentration in each of the third regions R3 is higher than the p-type impurity concentration in the first region R1, and has, for example, a value in a range of 1.0×10¹⁶ cm⁻³ or more and 4.0×10¹⁸ cm⁻³ or less.

Incidentally, as described above, the second regions R2 are each formed from the contact layer 26 up to the depth that reaches the lower cladding layer 21 in the semiconductor stack section 20. At this time, an interface between the bottom surface of each of the second regions R2 and the lower cladding layer 21 is formed at a position that is on the substrate 10 side and away from the active layer 23, and serves as a p-n junction. The bottom surface of each of the second regions R2 is the p-n junction formed by the second region R2 and the lower cladding layer 21. That is, the semiconductor stack section 20 has the p-n junction at both sides of the ridge 20A at positions that are on the substrate 10 side and away from the active layer 23. The p-n junction prevents electrons from being injected from the lower electrode layer 33 into the active layer 23.

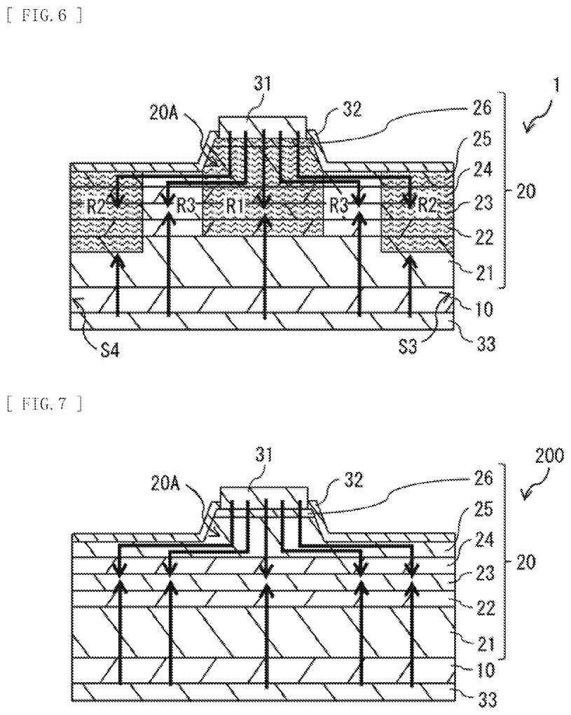

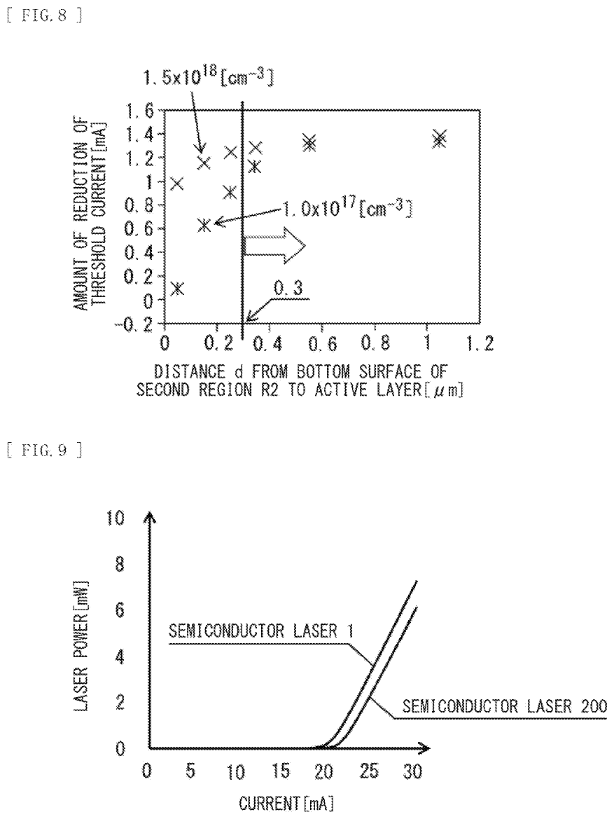

Here, in a laser diode, a current flows as a result of recombination of electrons and holes, and light emission occurs accordingly. In the semiconductor laser 1, the low-resistance upper cladding layer 25 is provided on both sides of the ridge 20A as well. The holes injected from the upper electrode layer 31 can reach the vicinity of the end faces S3 and S4 through the upper cladding layer 25. However, in the semiconductor stack section 20, the second region R2 is formed on each of both sides of the ridge 20A, and the p-n junction is formed at the positions that are on the substrate 10 side and away from the active layer 23. Accordingly, for example, as illustrated in FIG. 6, the electrons injected from the lower electrode layer 33 are prevented by the p-n junction from recombining with the holes injected from the upper electrode layer 31. As a result, an amount of current (a current leakage amount) flowing through both sides of the ridge 20A is greatly reduced as compared with a typical semiconductor laser 200 in which the second region R2 is not provided as illustrated in FIG. 7, for example. The amount of current (the current leakage amount) flowing through both sides of the ridge 20A becomes smaller as the distance from the bottom surface (i.e., the p-n junction described above) of the second region R2 to the active layer 23 becomes larger. The distance d from the bottom surface (i.e., the p-n junction described above) of the second region R2 to the active layer 23 is preferably 0.3 μm or more, for example, as illustrated in FIG. 8. Note that a horizontal axis of FIG. 8 is the distance d from the bottom surface (i.e., the p-n junction described above) of the second region R2 to the active layer 23, and a vertical axis of FIG. 8 is the amount of reduction of the threshold current. FIG. 8 illustrates simulation results where the p-type impurity concentration of the second region R2 was 1.5×10¹⁸ cm⁻³ and where the p-type impurity concentration of the second region R2 was 1.0×10¹⁷ cm⁻³. It can be appreciated from FIG. 8 that the amount of reduction of the threshold current, where the p-type impurity concentration of the second region R2 is 1.0×10¹⁷ cm ³, becomes 50% or more of the amount of reduction of the threshold current, where the amount of reduction of the threshold current becomes the greatest (where the p-type impurity concentration of the second region R2 is 1.5×10¹⁸ cm⁻³), is when the distance d is equal to or greater than 0.3 μm.

From the above, it can be appreciated that the second regions R2 each function as a high resistance region in the semiconductor stack section 20. As a result of each of the second regions R2 functioning as the high resistance regions, a current path of the semiconductor laser 1 becomes narrower than a current path of the semiconductor laser 200 by the amount resulting from the provision of each of the second regions R2. Consequently, for example, as illustrated in simulation results of FIG. 9, the threshold current of the semiconductor laser 1 becomes lower than the threshold current of the semiconductor laser 200. Note that, for the simulation of FIG. 9, it is possible to use a simulator using the Maxwell's equation, the Poisson's equation, the rate equation, or the like.

The semiconductor stack section 20 further has the fourth region R4 in each of a region that includes the resonator end face S1 and a region that includes the resonator end face S2. The fourth regions R4 are each a region that includes the resonator end faces S1 and S2 in the semiconductor stack section 20, and are each formed at a position that includes at least the active layer 23. The fourth regions R4 are each formed not only in the p-type semiconductor layer in the semiconductor stack section 20 but also up to the inside of the n-type semiconductor layer, for example, and are each formed from the contact layer 26 up to a depth that reaches the lower cladding layer 21 in the semiconductor stack section 20, for example.

The fourth regions R4 are each an impurity region containing a p-type impurity. The p-type impurity contained in each of the fourth regions R4 is, for example, Zn. The p-type impurity concentration in each of the fourth regions R4 is higher than the p-type impurity concentration in the first region R1, and has, for example, a value in a range of 1.0×10¹⁷ cm⁻³ or more and 2.0×10¹⁹ cm⁻³ or less. The fourth regions R4 each may be in contact with the ends of the respective second regions R2, for example, as illustrated in FIG. 4.

Here, the resonator end faces S1 and S2 are planes in which crystals are discontinuously cut off. Accordingly, a large number of dangling bonds are formed in the resonator end faces S1 and S2. The dangling bond acts as a non-light-emitting recombination center. Thus, carriers (electron-hole pairs) injected from the upper electrode layer 31 and the lower electrode layer 33 recombine at these non-light-emitting recombination centers, and the energies generated at this time are converted into heat. In addition, at the non-light-emitting recombination center, the effective energy-band gap is smaller than that at a central portion between the resonator end faces S1 and S2. Hence, light (recombined light) that has traveled back and forth between the resonator end faces S1 and S2 is easily absorbed by the non-light-emitting recombination center. The energy of the absorbed light generates carriers and heat is generated by the recombination at the non-light-emitting recombination center. Thus, in the non-light-emitting recombination center, the light absorption and the localized heat generation are promoted, which can eventually cause a catastrophic optical damage (Catastrophic Optical Damage: COD).

To avoid the COD, it is effective to make the energy-band gap at the resonator end faces S1 and S2 larger than that at the central portion between the resonator end faces S1 and S2. Such band gap structures in the resonator end faces S1 and S2 are referred to as the window structures. In the semiconductor laser 1, the window structures 10A and 10B are formed by providing the fourth regions R4 in the vicinity of the resonator end faces S1 and S2. That is, the fourth regions R4 are impurity regions provided to form the window structures in the vicinity of the resonator end faces S1 and S2. Accordingly, although the fourth region R4 has a configuration common to the second region R2 described above, the fourth region R4 is different from the above-described second region R2 in term of formation purpose.

[Manufacturing Method]

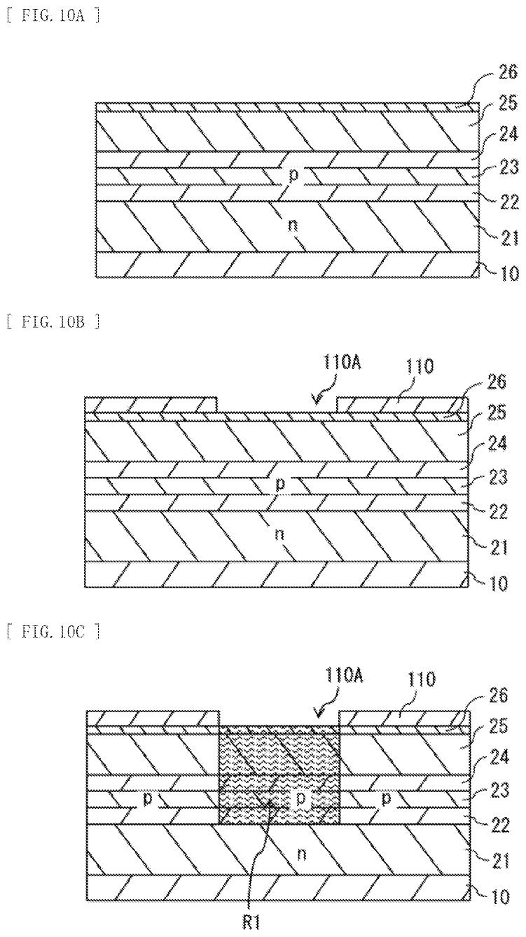

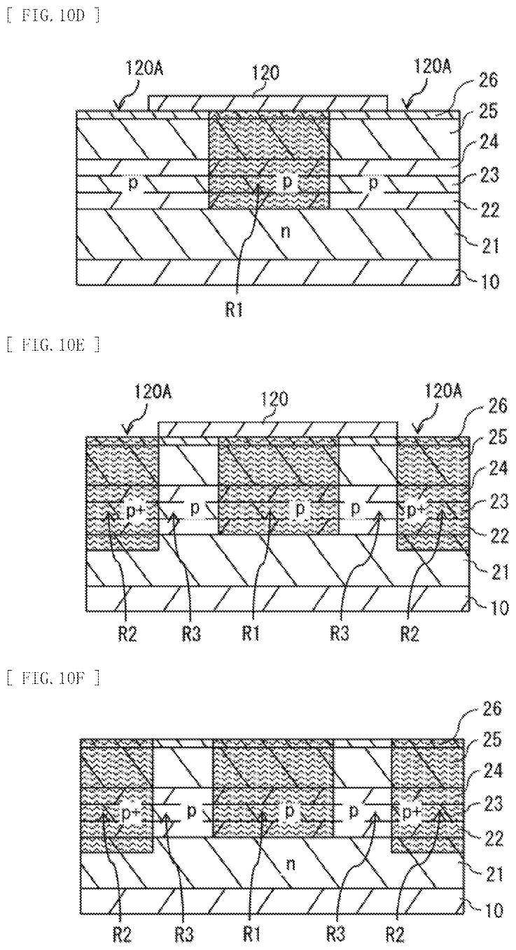

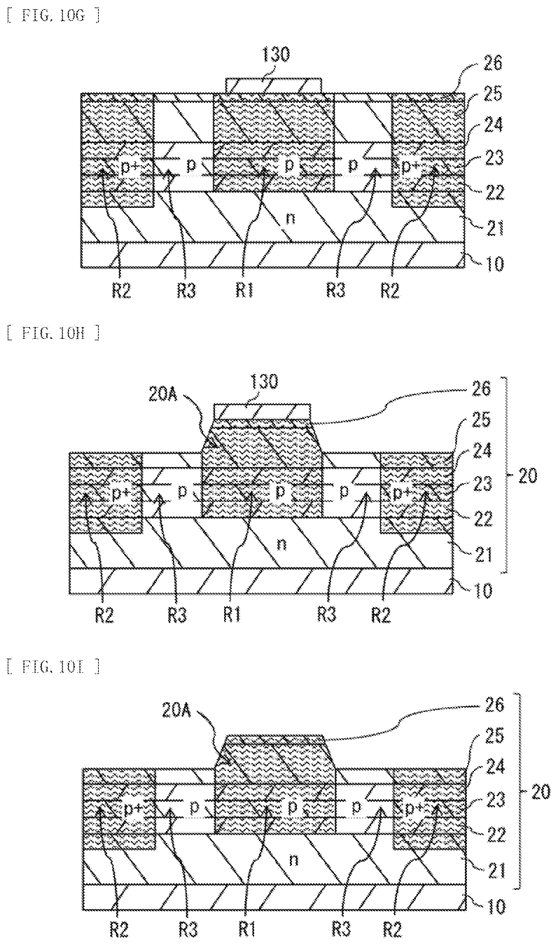

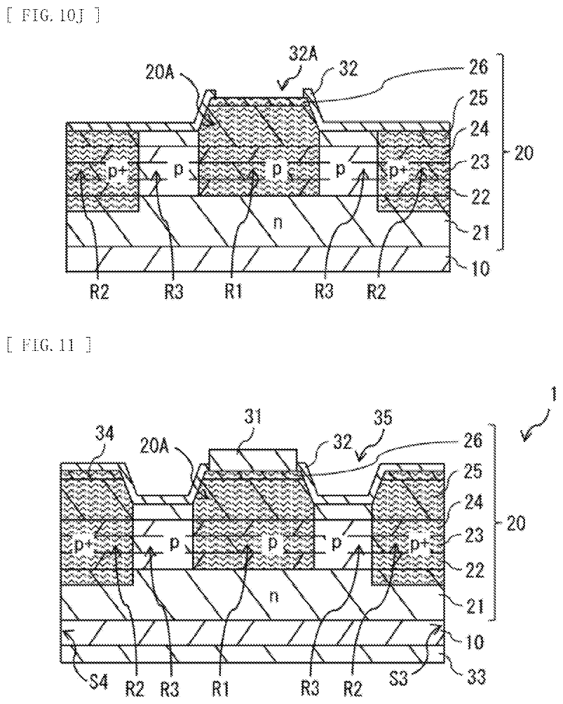

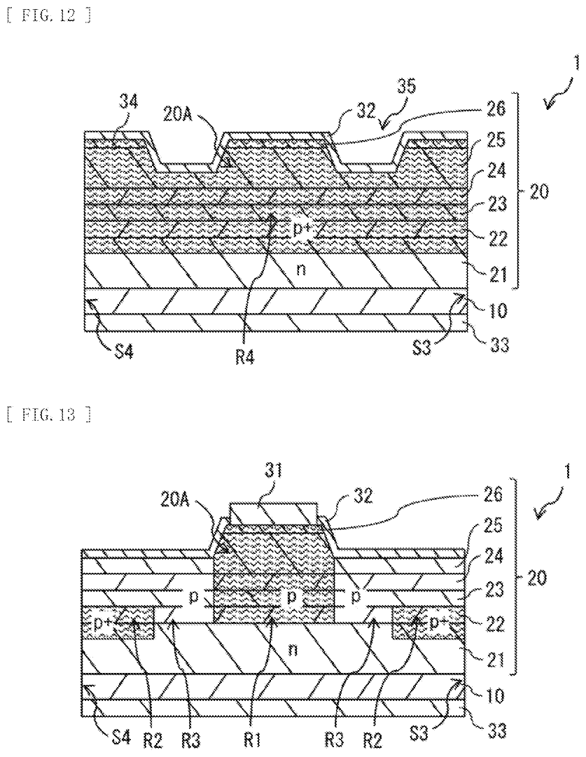

Next, a method of manufacturing the semiconductor laser 1 will be described with reference to FIGS. 10A to 10J. FIG. 10A illustrates an example of a cross-sectional configuration of a wafer in a manufacturing process of the semiconductor laser 1. FIG. 10B illustrates an example of a cross-sectional configuration of the wafer in a manufacturing process following FIG. 10A. FIG. 10C illustrates an example of a cross-sectional configuration of the wafer in a manufacturing process following FIG. 10B. FIG. 10D illustrates an example of a cross-sectional configuration of the wafer in a manufacturing process following FIG. 10C. FIG. 10E illustrates an example of a cross-sectional configuration of the wafer in a manufacturing process following FIG. 10D. FIG. 10F illustrates an example of a cross-sectional configuration of the wafer in a manufacturing process following FIG. 10E. FIG. 10G illustrates an example of a cross-sectional configuration of the wafer in a manufacturing process following FIG. 10F. FIG. 10H illustrates an example of a cross-sectional configuration of the wafer in a manufacturing process following FIG. 10G. FIG. 10I illustrates an example of a cross-sectional configuration of the wafer in a manufacturing process following FIG. 10H. FIG. 10J illustrates an example of a cross-sectional configuration of the wafer in a manufacturing process following FIG. 10I. Note that, in FIGS. 10A to 10I, both side surfaces correspond to portions to be eventually subjected to the cleavage with respect to the wafer.

To manufacture the semiconductor laser 1, a compound semiconductor is collectively formed on the substrate 10 that includes an Si-doped n-type GaAs, for example, by an epitaxial crystal growth method such as a MOCVD (Metal Organic Chemical Vapor Deposition: metal organic chemical vapor deposition) method. At this time, as a raw material of the compound semiconductor, for example, a methyl-based organometallic gas such as trimethylaluminum (TMAl), trimethylgallium (TMGa), trimethylindium (TMIn), or arsine (AsH3) is used.

First, the substrate 10 (the wafer) is placed in a MOCVD oven. Next, the lower cladding layer 21, the lower guide layer 22, the active layer 23, the upper guide layer 24, the upper cladding layer 25, and the contact layer 26 are formed in this order on the substrate 10 (FIG. 10A). Next, the substrate 10 (the wafer) is removed from the MOCVD oven. Next, a resist layer 110 having an opening 110A at a predetermined position is formed on a surface of the contact layer 26 (FIG. 10B). Subsequently, Zn is diffused through the opening 110A to a depth that reaches the lower guide layer 22 from the contact layer 26. This forms the first region R1 (FIG. 10C). Thereafter, the resist layer 110 is removed.

Next, a resist layer 120 having an opening 120A at a predetermined position is formed on a surface of the contact layer 26 (FIG. 10D). Subsequently, Zn is diffused through the opening 120A to a depth that reaches the lower cladding layer 21 from the contact layer 26. This forms the second region R2 (FIG. 10E). At this time, the fourth regions R4 may be formed together. Thereafter, the resist layer 120 is removed (FIG. 10F).

Note that, for the diffusion of Zn described above, it is possible to use a solid-state diffusion method using a ZnO film, or a vapor phase diffusion method or the like. For example, out of a surface of the contact layer 26, a ZnO film is formed at a position exposed inside the opening 110A or the opening 120A and the solid-state diffusion is performed, following which the ZnO film is peeled off, and SiN or the like is used to cover the entire surface of the contact layer 26. Thereafter, by annealing the substrate 10 (the wafer), Zn diffuses deeply from a surface layer of the contact layer 26, making it possible to control the Zn concentration to a desired concentration.

Next, a hard mask 130 having a predetermined pattern is formed on a surface of the contact layer 26 using, for example, a CVD method (FIG. 10G). The hard mask 130 is, for example, a SiO₂ film. Next, the contact layer 26 and the upper cladding layer 25 are selectively etched by, e.g., dry etching while using the hard mask 130 as a mask. Consequently, the ridge 20A is formed immediately below the hard mask 130, and the semiconductor stack section 20 including the ridge 20A is formed (FIG. 10H). Thereafter, the hard mask 130 is removed (FIG. 10I).

Next, the insulation layer 32 having an opening 32A is formed on the upper surface of the ridge 20A by, e.g., CVD, sputtering, or the like (FIG. 10J). Next, the upper electrode layer 31 is formed inside the opening 32A by, e.g., evaporation. Further, the lower electrode layer 33 is formed on the back surface of the substrate 10 (the wafer) by using evaporation or the like, for example. Next, the substrate 10 (the wafer) is subjected to the cleavage to form the resonator end faces S1 and S2. Further, the substrate 10 is cut by means of dicing to form the end faces S3 and S4. Finally, the reflection preventing film is formed on the resonator end face S1 and the multilayer reflection film is formed on the resonator end face S2. In this way, the semiconductor laser 1 is manufactured.

[Operation]

In the semiconductor laser 1 having the configuration described above, when a predetermined voltage is applied between the upper electrode layer 31 and the lower electrode layer 33, a current is injected into the active layer 23 through the ridge 20A to thereby generate emission of light resulting from the recombination of electrons and holes. The light is reflected by the pair of resonator end faces S1 and S2 and is confined by the lower cladding layer 21 and the upper cladding layer 25, resulting in laser oscillation at a predetermined oscillation wavelength. At this time, in the semiconductor stack section 20, an optical waveguide region in which the oscillated laser light is guided is formed. Then, the laser light of the oscillation wavelength is outputted from one of the resonator end faces to the outside. The optical waveguide region is generated in a region immediately below the ridge 20A centered on the active layer 23.

[Effect]

Next, an effect of the semiconductor laser 1 will be described in comparison with a comparative example.

In a case where a ridge is provided in a semiconductor laser of an edge emission type, a current leakage to both sides of the ridge occurs, lowering a utilization efficiency of a current and making it not possible to obtain a good threshold current in some cases. In contrast, according to the present embodiment, the second region R2 having the p-type impurity concentration that is higher than the p-type impurity concentration of the region (the first region R1) facing the ridge 20A is provided at each of the positions that are positioned on both sides of the ridge 20A and that are deeper than at least the active layer 23. Thus, in the semiconductor stack section 20, the p-n junction is formed at both sides of the ridge 20A at the positions that are on the substrate 10 side and away from the active layer 23. Hence, for example, as illustrated in FIG. 6, the electrons injected from the lower electrode layer 33 are prevented by the p-n junction from recombining with the holes injected from the upper electrode layer 31. As a result, the amount of current (the current leakage amount) flowing through both sides of the ridge 20A is greatly reduced as compared with, for example, the typical semiconductor laser 200 in which the second region R2 is not provided as illustrated in FIG. 7. Accordingly, the second regions R2 each function as the high resistance region in the semiconductor stack section 20. As a result of each of the second regions R2 functioning as the high resistance region, the current path of the semiconductor laser 1 becomes narrower than the current path of the semiconductor laser 200 by the amount resulting from the provision of each of the second regions R2. Consequently, for example, as illustrated in FIG. 9, it is possible to make the threshold current of the semiconductor laser 1 lower than the threshold current of the semiconductor laser 200. In addition, because the amount of current (the current leakage amount) flowing through both sides of the ridge 20A is greatly reduced, wasteful heat generation is suppressed owing to improvement of an efficiency, making it possible to reduce a growth rate of a defect in the active layer 23 and achieve good reliability.

In addition, according to the present embodiment, the second regions R2 each include the end faces S3 and S4. Thus, it is possible to reduce a dark current at the end faces S3 and S4 by each of the second regions R2. Hence, it is possible to further lower the threshold current of the semiconductor laser 1.

In addition, according to the present embodiment, the second regions R2 are each provided from the portion corresponding to the foot of the ridge 20A (the surface of the upper cladding layer 25) to the position deeper than the active layer 23. In this case, because it is possible to form each of the second regions R2 by, for example, the Zn-diffusion, it is possible to reduce a damage to the semiconductor stack section 20 caused by the formation of each of the second regions R2. Hence, it is possible to reduce the current leakage amount resulting from the damage formed on the semiconductor stack section 20.

In addition, according to the present embodiment, the active layer 23 is provided in the p-type semiconductor layer. Thus, it is possible to increase a distance between the p-n junction, formed at the interfaces between each of the second regions R2 and the lower cladding layer 21, and the active layer 23 as compared with, for example, a case where the active layer 23 is provided between the p-type semiconductor layer and the n-type semiconductor layer. It is possible to make the likelihood of the recombination at both sides of the ridge 20A lower as the distance becomes larger, and to greatly reduce the amount of current (the current leakage amount) flowing through both sides of the ridge 20A.

In addition, according to the present embodiment, the impurity regions (the third regions R3) having the p-type impurity concentration that is higher than the p-type impurity concentration of the region (the first region R1) facing the ridge 20A form the window structures 10A and 10B. Thus, it is possible to reduce not only the amount of current (the current leakage amount) flowing through both sides of the ridge 20A but also the amount of current (the current leakage amount) flowing through the resonator end faces S1 and S2. Hence, it is possible to lower the threshold current of the semiconductor laser 1. Further, it is also possible to prevent the generation of the COD by the window structures 10A and 10B and improve reliability of a device as well.

In addition, in the present embodiment, allowing the p-type impurity of each of the second regions R2 to be Zn and allowing the p-type impurity of each of the third regions R3 to be Zn as well make it possible to form each of the second regions R2 and each of the third regions R3 collectively by the Zn diffusion. In this case, it is possible to suppress an increase in takt time and a manufacturing cost.

### 2. MODIFICATION EXAMPLES

Next, modification examples of the semiconductor laser 1 according to the above embodiment will be described.

### Modification Example A

FIG. 11 illustrates one modification example of a cross-sectional configuration of the semiconductor laser 1 illustrated in FIG. 2. FIG. 12 illustrates one modification example of a cross-sectional configuration of the semiconductor laser 1 illustrated in FIG. 3. In the above-described embodiment, the semiconductor stack section 20 may have a band-shaped groove 35 at each of positions that are at both sides of the ridge 20A and that are between the ridge 20A and portions (i.e., the third regions R3) facing the second regions R2 in a stack direction. The groove 35 has a depth that does not reach the active layer 23.

In this case, the semiconductor stack section 20 has bases 34 between the groove 35 and the end face S3 and between the groove 35 and the end face S4, respectively. The base 34 corresponds to a remaining portion that has not been etched at the time when the ridge 20A is formed by forming, using etching in the manufacturing process, two grooves 35 that are parallel to each other. Accordingly, in addition to the upper cladding layer 25, the base 34 also includes the contact layer 26 that is more electrically conductive than the upper cladding layer 25. A height of the base 34 is approximately equal to a height of the ridge 20A. Thus, by providing the base 34, it is possible to avoid concentration of external force and stress on the ridge 20A. Hence, it is possible to improve durability of the semiconductor laser 1.

As described above, in addition to the upper cladding layer 25, the base 34 also includes the contact layer 26 that is more electrically conductive than the upper cladding layer 25. Accordingly, the amount of current (the current leakage amount) flowing through both sides of the ridge 20A via the contact layer 26 or the upper cladding layer 25 can increase. However, in the present modification example, similarly to the above embodiment, the second region R2 is formed on each of both sides (that is, regions facing the bases 34) of the ridge 20A. Accordingly, although the bases 34 are provided, the current leakage at both sides of the ridge 20A is suppressed by the second regions R2. As a result, it is possible to lower the threshold current of the semiconductor laser 1. In addition, because the amount of current (the current leakage amount) flowing through both sides of the ridge 20A is greatly reduced, wasteful heat generation is suppressed owing to improvement of an efficiency, making it possible to reduce a growth rate of a defect in the active layer 23 and achieve good reliability.

### Modification Example B

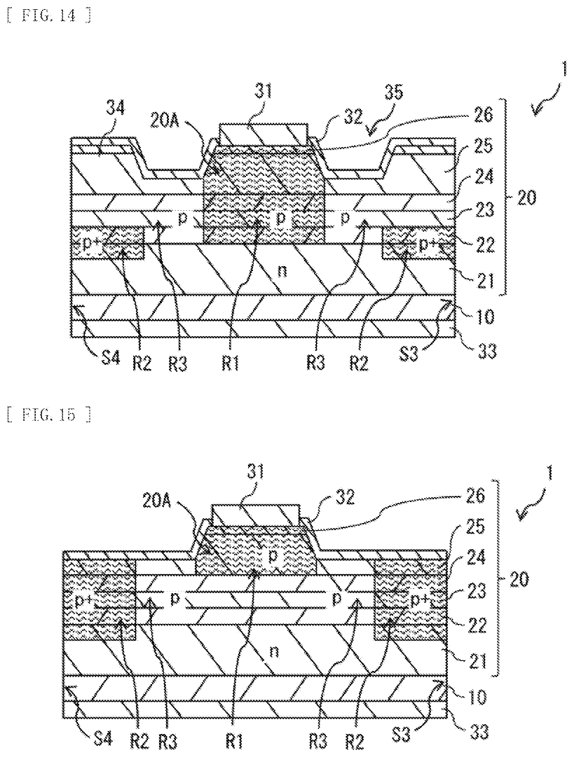

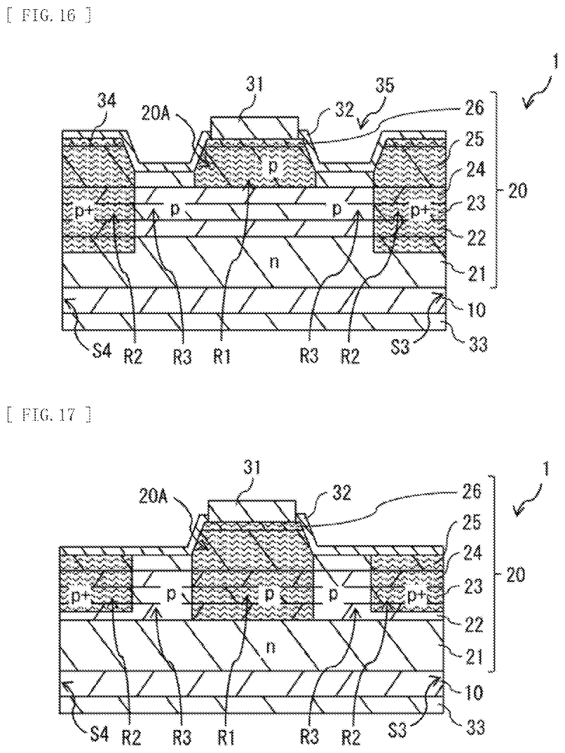

FIG. 13 illustrates one modification example of a cross-sectional configuration of the semiconductor laser 1 illustrated in FIG. 2. FIG. 14 illustrates one modification example of a cross-sectional configuration of the semiconductor laser 1 illustrated in FIG. 11. In the above embodiment and the modification example A thereof, the second regions R2 each may be provided only between the active layer 23 and the substrate 10. At this time, it is preferable that the second regions R2 each be provided in contact with the active layer 23. It is possible to form each of the second regions R2 by implanting Zn to a desired depth of the semiconductor stack section 20 using, for example, an ion implantation method. Even in a case where the second regions R2 are each provided only between the active layer 23 and the substrate 10, it is possible to achieve effects that are similar to those of the above embodiment and the modification example A thereof.

### Modification Example C

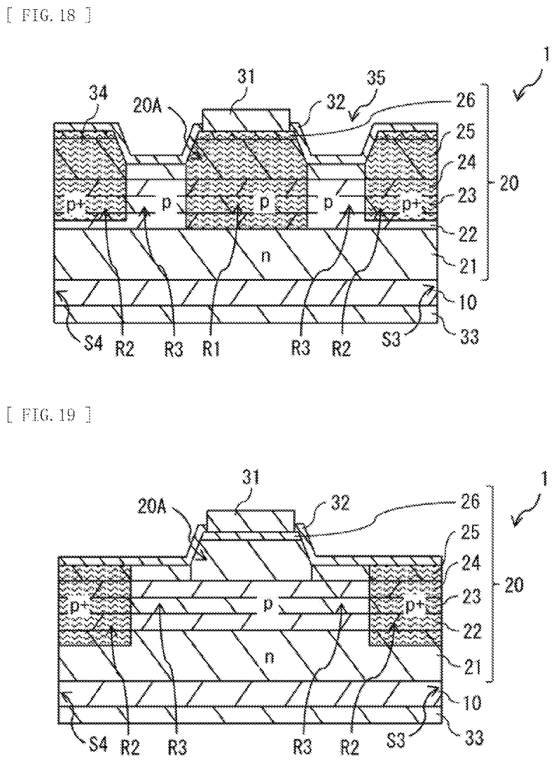

FIG. 15 illustrates one modification example of a cross-sectional configuration of the semiconductor laser 1 illustrated in FIG. 2. FIG. 16 illustrates one modification example of a cross-sectional configuration of the semiconductor laser 1 illustrated in FIG. 11. In the above embodiment and the modification example A thereof, the first region R1 may be provided only in the p-type semiconductor layer. For example, in the above embodiment and the modification example A thereof, the first region R1 may be formed only at a portion that faces the ridge 20A, out of the upper cladding layer 25 and the contact layer 26. Even in such a case, it is possible to achieve effects that are similar to those of the above embodiment and the modification example A thereof.

### Modification Example D

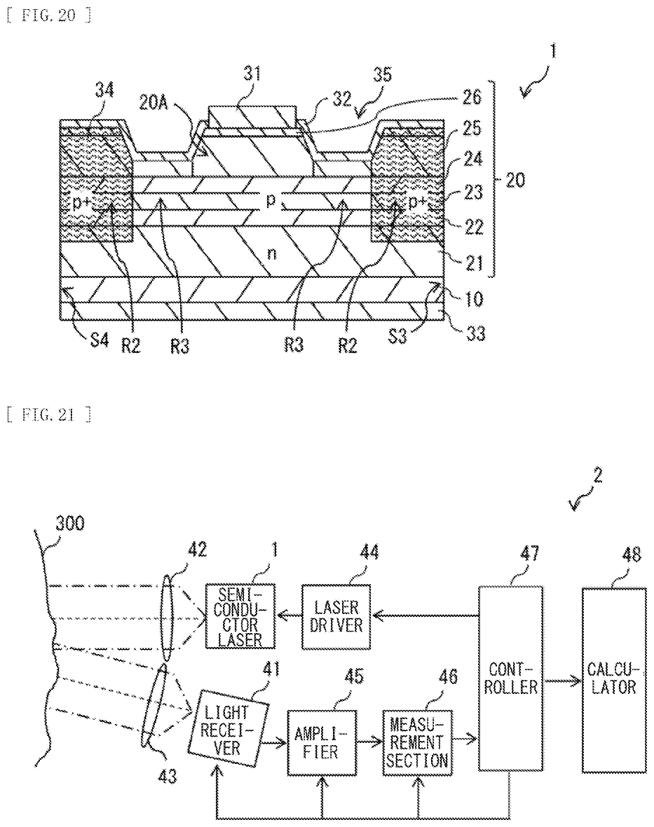

FIG. 17 illustrates one modification example of a cross-sectional configuration of the semiconductor laser 1 illustrated in FIG. 2. FIG. 18 illustrates one modification example of a cross-sectional configuration of the semiconductor laser 1 illustrated in FIG. 11. In the above embodiment and the modification example A thereof, the second regions R2 each may be formed only in the p-type semiconductor layer in the semiconductor stack section 20. For example, in the above-described embodiment and the modification example A thereof, the second regions R2 each may be formed from the contact layer 26 or the upper cladding layer 25 up to a depth that reaches the lower guide layer 22 in the semiconductor stack section 20. Even in such a case, it is possible to achieve effects that are similar to those of the above embodiment and the modification example A thereof.

### Modification Example E

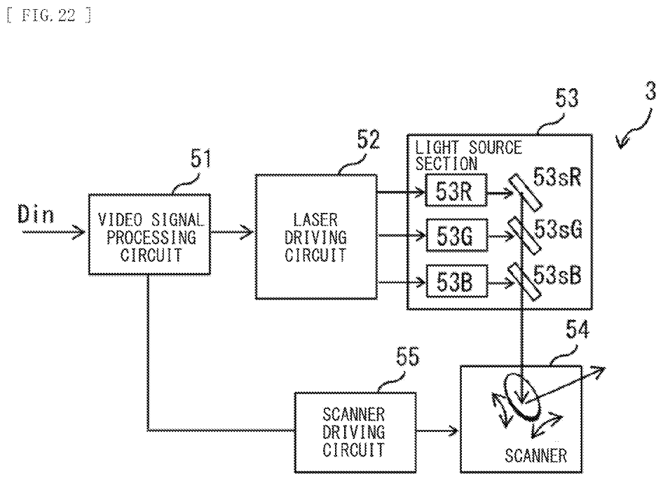

FIG. 19 illustrates one modification example of a cross-sectional configuration of the semiconductor laser 1 illustrated in FIG. 2. FIG. 20 illustrates one modification example of a cross-sectional configuration of the semiconductor laser 1 illustrated in FIG. 11. In the above embodiment and the modification examples A to D thereof, the first region R1 may be omitted. Even in such a case, it is possible to achieve effects that are similar to those of the above embodiment and the modification example A thereof.

### Modification Example F

In the above embodiment and the modification examples A to E thereof, the conductivity types may be reversed. For example, in the above embodiment and the modification examples A to E thereof, the p-type may be the n-type and the n-type may be the p-type. Even in such a case, it is possible to achieve effects that are similar to those of the above embodiment and the modification examples A to E thereof.

### Modification Example G

In the above embodiment and the modification examples A to F thereof, a semiconductor material structuring the semiconductor stack section 20 may be, for example, a group III-V semiconductor including nitrogen (N), boron (B), antimony (Sb), and phosphorus (P).

### Modification Example H

In the above embodiment and the modification examples A to G thereof, a resin layer embedding the ridge 20A may be provided instead of the insulation layer 32. Further, in the above embodiment and the modification examples A to G thereof, the insulation layer 32 may be omitted.

### Modification Example I

In the above embodiment and the modification examples A to H thereof, the second region R2 may be provided at at least a portion of a region not facing the ridge 20A. In addition, in the above embodiment and the modification examples A to H, the second region R2 may include at least a portion of the end faces S3 and S4. Even in such a case, the amount of current (the current leakage amount) flowing through both sides of the ridge 20A is reduced as compared with, for example, the typical semiconductor laser 200 in which the second region R2 is not provided. Consequently, it is possible to make the threshold current of the semiconductor laser 1 lower than the threshold current of the semiconductor laser 200. In addition, because the amount of current (the current leakage amount) flowing through both sides of the ridge 20A is reduced, wasteful heat generation is suppressed owing to improvement of an efficiency, making it possible to reduce a growth rate of a defect in the active layer 23 and achieve good reliability.

### 3. SECOND EMBODIMENT

Next, a distance measuring apparatus 2 according to a second embodiment of the present disclosure will be described. FIG. 19 illustrates an example of a schematic configuration of the distance measuring apparatus 2. The distance measuring apparatus 2 measures a distance to an object under test 300 by a TOF (Time Of Flight) method. The distance measuring apparatus 2 includes the semiconductor laser 1 as a light source. The distance measuring apparatus 2 includes, for example, the semiconductor laser 1, a light receiver 41, lenses 42 and 43, a laser driver 44, an amplifier 45, a measurement section 46, a controller 47, and a calculator 48.

The light receiver 41 detects light reflected by the object under test 300. The light receiver 41 is configured by, for example, a photodetector. The light receiver 41 may be configured by an avalanche photodiode (APD), a single photon avalanche diode (SPAD), or a multi-pixel single photon avalanche diode (MP-SPAD), or the like. The lens 42 is a lens for collimating the light outputted from the semiconductor laser 1, and is a collimating lens. The lens 43 is a lens that condenses the light reflected by the object under test 300 and guides the condensed light to the light receiver 41. The lens 43 is a condenser lens.

The laser driver 44 is, for example, a driver circuit for driving the semiconductor laser 1. The amplifier 45 is, for example, an amplifier circuit for amplifying a detection signal outputted from the light receiver 41. The measurement section 46 is, for example, a circuit for generating a signal corresponding to a difference between a signal inputted from the amplifier 45 and a reference signal. The measurement section 46 is configured by, for example, a Time to Digital Converter (TDC). The reference signal may be a signal inputted from the controller 47, or may be an output signal of a detecting unit that directly detects the output of the semiconductor laser 1. The controller 47 is, for example, a processor that controls the light receiver 41, the laser driver 44, the amplifier 45, and the measurement section 46. The calculator 48 is a circuit that calculates distance information on the basis of the signal generated by the measurement section 46.

In the present embodiment, the semiconductor laser 1 is used as the light source in the distance measuring apparatus 2. Thus, it is possible to emit a high-output laser light. Hence, it is possible to improve a detection accuracy.

### 4. THIRD EMBODIMENT

Next, a projector 3 according to a third embodiment of the present disclosure will be described. FIG. 20 illustrates an example of a schematic configuration of the projector 3. The projector 3 is a device that projects an image based on a picture signal Din inputted from the outside onto a screen or the like. The projector 3 includes a video signal processing circuit 51, a laser driving circuit 52, a light source section 53, a scanner 54, and a scanner driving circuit 55.

The video signal processing circuit 51 generates a projection picture signal for each color on the basis of the picture signal Din. The laser driving circuit 52 controls a crest value of a current pulse to be applied to later-described light sources 53R, 53G, and 53B, on the basis of the projection picture signal for each color.

The light source section 53 has a plurality of light sources, e.g., three light sources 53R, 53G, and 53B. The three light sources 53R, 53G, and 53B are used, for example, as laser light sources that output pieces of laser light having wavelengths of red (R), green (G), and blue (B). At least one of the light sources 53B or 53G includes the semiconductor laser 1 according to the above-described first embodiment and the modification examples thereof. The pieces of laser light outputted from the three light sources 53R, 53G, and 53B are caused to be substantially pieces of parallel light by collimating lenses, following which the pieces of parallel light are bundled to one laser light by beam splitters 53sR, 53sG, and 53sB, for example. The beam splitter 53sR reflects red light, for example. The beam splitter 53sG reflects green light and transmits red light, for example. The beam splitter 53sB reflects blue light and transmits red light and green light, for example.

The laser light having transmitted through or been reflected by the beam splitters 53sR, 53sG, and 53sB enters the scanner 54. The scanner 54 is configured by, for example, one biaxial scanner. The laser light that has entered the scanner 54 is modulated in the irradiation angle horizontally and vertically by the biaxial scanner before being projected onto the screen. Note that the scanner 54 may be configured to perform scanning horizontally and vertically using two uniaxial scanners.

Usually, the scanner 54 has a sensor that detects the irradiation angle derived from, for example, the biaxial scanner. The sensor outputs respective horizontal and vertical angular signals. These angular signals are inputted to the scanner driving circuit 55. The scanner driving circuit 55 drives the scanner 54 such that a desired irradiation angle is obtained, on the basis of the horizontal angular signal and the vertical angular signal inputted from the scanner 54, for example.

In the present embodiment, the semiconductor laser 1 according to the above-described first embodiment and modification examples thereof is used in at least one of the light sources 53B or 53G. Hence, it is possible to obtain high light emission intensity with low power consumption.

While the present disclosure has been described with reference to a plurality of embodiments, the present disclosure is not limited to the above embodiments, and various modifications can be made. It should be noted that the effects described in this specification are only exemplary. The effects of the present disclosure are not limited to the effects described herein. The present disclosure may have effects other than the effects described herein.

For example, the present disclosure may also be configured as follows.
(1)
   A semiconductor laser including
   a semiconductor stack section, the semiconductor stack section including
      a first semiconductor layer of a first conductivity type,
      a second semiconductor layer of a second conductivity type, the second semiconductor layer being stacked on the first semiconductor layer and including a ridge having a band shape, and
      an active layer, in which
   the semiconductor stack section has a first impurity region that is at least a portion of a region not facing the ridge and that is located at a position deeper than at least the active layer, the first impurity region having an impurity concentration of the second conductivity type higher than an impurity concentration of the second conductivity type in a region, of the second semiconductor layer, facing the ridge.
(2)
   The semiconductor laser according to (1), in which
   the semiconductor stack section has an end face on each of both sides of the ridge, and
   the first impurity region includes at least a portion of the end face.
(3)
   The semiconductor laser according to (1) or (2), in which the first impurity region is provided from a portion, of a surface of the second semiconductor layer, corresponding to a foot of the ridge to the position deeper than the active layer.
(4)
   The semiconductor laser according to any one of (1) to (3), in which the second semiconductor layer has a groove that is at least a portion of the region not facing the ridge and that is provided between the ridge and a portion facing the first impurity region in a stack direction, the groove having a band shape and having a depth that does not reach the active layer.
(5)
   The semiconductor laser according to any one of (1) to (4), in which the active layer is provided in the second semiconductor layer.
(6)
   The semiconductor laser according to any one of (1) to (5), in which
   the first conductivity type is an n-type,
   the second conductivity type is a p-type,
   an impurity of the second conductivity type contained in the region, of the second semiconductor layer, facing the ridge is C, and
   an impurity of the second conductivity type contained in the first impurity region is Zn.
(7)
   The semiconductor laser according to any one of (1) to (6), in which the semiconductor stack section includes an AlGaAs-based semiconductor material.
(8)
   The semiconductor laser according to any one of (1) to (7), in which
   a bottom surface of the first impurity region is a p-n junction formed by the first impurity region and the first semiconductor layer, and
   a distance from the bottom surface of the first impurity region to the active layer is 0.3 μm or more.
(9)
   The semiconductor laser according to any one of (1) to (8), in which the impurity concentration of the second conductivity type in the first impurity region is 6.0×10¹⁷/cm³ or more.
(10)
   The semiconductor laser according to any one of (1) to (9), in which
   the semiconductor stack section further includes, at each of both ends of the ridge, a resonator end face and a window structure that includes the resonator end face, and
   the window structure includes a second impurity region having an impurity concentration of the second conductivity type higher than the impurity concentration of the second conductivity type in the region, of the second semiconductor layer, facing the ridge.
(11)
   The semiconductor laser according to (10), in which an impurity of the second conductivity type contained in the second impurity region is Zn.
(12)
   An electronic apparatus that includes a semiconductor laser as a light source, the semiconductor laser including
   a semiconductor stack section, the semiconductor stack section including
      a first semiconductor layer of a first conductivity type,
      a second semiconductor layer of a second conductivity type, the second semiconductor layer being stacked on the first semiconductor layer and including a ridge having a band shape, and
      an active layer, in which
   the semiconductor stack section has an impurity region that is at least a portion of a region not facing the ridge and that is located at a position deeper than at least the active layer, the impurity region having an impurity concentration of the second conductivity type higher than an impurity concentration of the second conductivity type in a region, of the second semiconductor layer, facing the ridge.

According to the semiconductor laser and the electronic apparatus according to an embodiment of the present disclosure, at least a portion of the region not facing the ridge prevents electrons or holes from being transported to the active layer. Thus, it is possible to suppress a current leakage to both sides of the ridge. Hence, it is possible to achieve a good threshold current. It should be noted that the effects of the present disclosure are not necessarily limited to the effects described herein, and may be any of the effects described in this specification.

The present application claims the benefit of Japanese Priority Patent Application JP2018-214956 filed with the Japan Patent Office on Nov. 15, 2018, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A semiconductor laser comprising
a semiconductor stack section, the psemiconductor stack section including
a first semiconductor layer of a first conductivity type,
a second semiconductor layer of a second conductivity type, the second semiconductor layer being stacked on the first semiconductor layer and including a ridge having a band shape, and
an active layer, wherein
the semiconductor stack section has a first impurity region that is at least a portion of a region not facing the ridge and that is located at a position deeper than at least the active layer, the first impurity region having an impurity concentration of the second conductivity type higher than an impurity concentration of the second conductivity type in a region, of the second semiconductor layer, facing the ridge.

2. The semiconductor laser according to claim 1, wherein
the semiconductor stack section has an end face on each of both sides of the ridge, and
the first impurity region includes at least a portion of the end face.

3. The semiconductor laser according to claim 1, wherein the first impurity region is provided from a portion, of a surface of the second semiconductor layer, corresponding to a foot of the ridge to the position deeper than the active layer.

4. The semiconductor laser according to claim 1, wherein the second semiconductor layer has a groove that is at least a portion of the region not facing the ridge and that is provided between the ridge and a portion facing the first impurity region in a stack direction, the groove having a band shape and having a depth that does not reach the active layer.

5. The semiconductor laser according to claim 1, wherein the active layer is provided in the second semiconductor layer.

6. The semiconductor laser according to claim 1, wherein
the first conductivity type is an n-type,
the second conductivity type is a p-type,
an impurity of the second conductivity type contained in the region, of the second semiconductor layer, facing the ridge is C, and
an impurity of the second conductivity type contained in the first impurity region is Zn.

7. The semiconductor laser according to claim 1, wherein the semiconductor stack section includes an AlGaAs-based semiconductor material.

8. The semiconductor laser according to claim 1, wherein
a bottom surface of the first impurity region is a p-n junction formed by the first impurity region and the first semiconductor layer, and
a distance from the bottom surface of the first impurity region to the active layer is 0.3 μm or more.

9. The semiconductor laser according to claim 1, wherein the impurity concentration of the second conductivity type in the first impurity region is 6.0×10¹⁷/cm³ or more.

10. The semiconductor laser according to claim 1, wherein
the semiconductor stack section further includes, at each of both ends of the ridge, a resonator end face and a window structure that includes the resonator end face, and
the window structure includes a second impurity region having an impurity concentration of the second conductivity type higher than the impurity concentration of the second conductivity type in the region, of the second semiconductor layer, facing the ridge.

11. The semiconductor laser according to claim 10, wherein an impurity of the second conductivity type contained in the second impurity region is Zn.

12. An electronic apparatus that includes a semiconductor laser as a light source, the semiconductor laser comprising
a semiconductor stack section, the semiconductor stack section including
a first semiconductor layer of a first conductivity type,
a second semiconductor layer of a second conductivity type, the second semiconductor layer being stacked on the first semiconductor layer and including a ridge having a band shape, and
an active layer, wherein
the semiconductor stack section has an impurity region that is at least a portion of a region not facing the ridge and that is located at a position deeper than at least the active layer, the impurity region having an impurity concentration of the second conductivity type higher than an impurity concentration of the second conductivity type in a region, of the second semiconductor layer, facing the ridge.
